(19) United States
(12) Patent Application Publication
(10) Pub. No.: US 2023/0027970 A1
(43) Pub. Date: Jan. 26, 2023

(54) PHOTOVOLTAIC MODULE

(71) Applicant: DRACULA TECHNOLOGIES, VALENCE (FR)

(72) Inventors: Sadok BEN DKHIL, VALENCE (FR); Brice CRUCHON, GUILHERAND GRANGES (FR)

(21) Appl. No.: 17/787,291

(22) PCT Filed: Dec. 23, 2020
(86) PCT No.: PCT/FR2020/052623

§ 371 Date: Jun. 17, 2022

(30) Foreign Application Priority Data
Dec. 24, 2019 (FR) 1915542

(51) Int. Cl. H01L 51/00; H01L 51/44

(52) U.S. Cl. CPC H01L 51/0005; H01L 51/0037; H01L 51/441; H01L 51/0047

(57) ABSTRACT

The invention relates to a photovoltaic module comprising a glass substrate or a substrate made of polymer material and at least two photovoltaic cells, a first photovoltaic cell and a second photovoltaic cell, on said substrate.

The invention relates generally to photovoltaic modules, and in particular to photovoltaic modules comprising a plurality of organic photovoltaic cells (usually referred to by the acronym OPC).

Organic photovoltaic cell means, in the sense of the present invention, a photovoltaic cell in which at least the active layer consists of an organic material.

Photovoltaic modules with organic photovoltaic cells represent a real interest in the field of photovoltaics. Indeed, the possibility of substituting inorganic semiconductors generally used in photovoltaic cells, such as silicon, copper, indium, gallium, selenium, or cadmium telluride, increases the number of systems that can be realized and therefore the possibilities of use. The development of marketable photovoltaic modules with several organic photovoltaic cells is currently a major challenge.

In recent years, the development of organic photovoltaic cells has evolved through the use of the inkjet printing technique for their implementation^{[1],[2]}. Moreover, in 2014, the Applicant developed a method for manufacturing photovoltaic cells using that technique to print part of the layers of these cells^{[3]}.

Initially, many studies focused on the realization of an interfacial layer by inkjet printing of an ink comprising a polymer blend of poly(3,4-ethylenedioxythiophene) and sodium poly(styrene sulfonate), usually designated by the acronym PEDOT:PSS. Later, research in this field focused on inkjet printing of the photovoltaic active layer, which is usually composed of two organic materials, one electron donor and the other electron acceptor. For an active layer of an organic nature, P₃HT:PCBM (P₃HT which stands for poly(3-hexylthiophene) and PCBM which stands for [6,6]-phenyl-C₇₁-butanoate of methyl) are conventionally used.

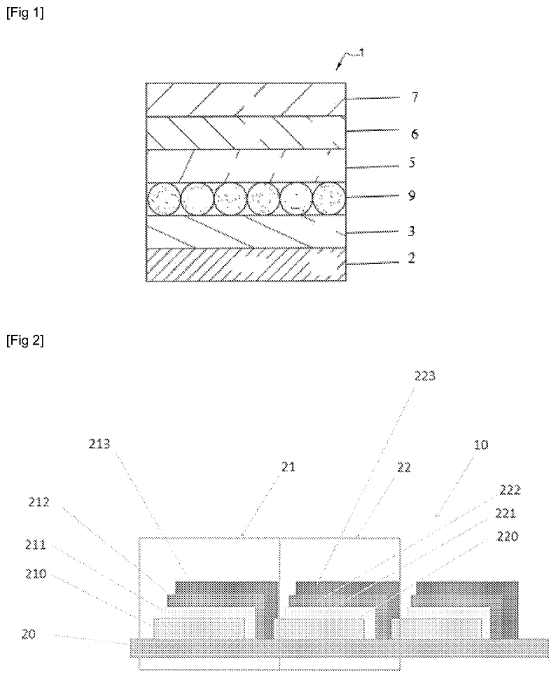

As shown in FIG. 1, in a currently used normal or conventional photovoltaic cell 1, a first interfacial layer 9, for example made of PEDOT PSS, is applied to a layer of indium tin oxide 3 (ITO), which serves as an anode and is itself applied to a substrate. Above the first interfacial layer 9 is applied a photovoltaic active layer 5 which can for example be based on P₃HT:PCBM, and above this photovoltaic active layer 5 is applied a second interfacial layer 6 above which is applied an opaque top electrode 7 usually made of aluminum, or silver when this layer is applied by inkjet printing, and which serves here as cathode.

There are also currently photovoltaic cells with an inverse structure. The major difference compared to the conventional structure is that the interfacial layer in PEDOTT:PSS is located between the active layer and the upper electrode which is the anode. It should be noted that reverse-structured photovoltaic cells have the advantage of better air stability than conventionally structured photovoltaic cells, and furthermore generally have higher conversion efficiencies.

In the sense of the present invention, the conversion efficiency of a photovoltaic cell means the ratio of the maximum electrical power delivered by the cell over the incident light output, for a given spectral distribution and intensity.

It is to be noted, moreover, that the above mentioned high conversion efficiencies are ensured when the photovoltaic modules of the current state of the art are exposed to an external radiation, that is exposed to a light intensity higher than 2000 lux and in particular to a radiation under standard conditions AM1.5 which corresponds to a light intensity of exposure having an output of 100 mW/cm2 which is equivalent to a light intensity approximately equal to 100000 Lux. In particular, the high number of photo-generated charges requires the use of an anode with very high electrical conductivity to guarantee good collection of photo-generated charges in the active layer in order to minimize, among other things, the accumulation phenomenon. In particular, the high number of photo-generated charges requires the use of an anode with very high electrical conductivity to guarantee good collection, in the active layer, of photo-generated charges so as to minimize the accumulation phenomenon at the level of the interfacial layers. This is why, generally, in the case of an inverse structure, the upper electrode (or anode) is opaque and made of silver. In this case, the conversion efficiency can reach laboratory-scale values between 15 and 17% for organic photovoltaic cells. However, on an industrial scale, the conversion efficiency, this time of the manufactured photovoltaic modules, is half or less.

However, photovoltaic modules of the current state of the art cannot be used effectively under indoor radiation, that is under a power of 0.3 mW/cm², equivalent to 1000 lux.

This low conversion efficiency, when the photovoltaic modules are exposed to indoor radiation, is due in particular to the fact that photovoltaic modules comprising organic photovoltaic cells of the current state of the art have a high series resistance due to the number of layers forming the organic photovoltaic cell and thus the photovoltaic module, and insufficiently high shunt resistances, the shunt resistances continuing to decrease with decreasing light intensity. Therefore, these resistance levels do not optimize the performance and fill factor of organic photovoltaic modules of the current state of the art. Indeed, it is known that the shunt resistance must be large enough for a better output power and a good fill factor of the photovoltaic module. Indeed, at a low shunt resistance, the current collapses strongly which means that the power loss is high and the fill factor is low.

Furthermore, the low conversion efficiency of the photovoltaic modules of the current state of the art is also due to the fact that they have high dead surfaces, because the deposition of the different constituent layers of each of the organic photovoltaic cells of the photovoltaic modules are applied to the substrate in a staggered manner, so that each layer of the organic photovoltaic cell is partly in contact with the substrate in order to avoid the creation of short circuits which can be caused by the reverse feedback effect of the material deposited in the liquid state, for example. Consequently, the photovoltaic modules of the current state of the art have small active surfaces which do not allow the generating of a sufficient photo-current when the incident light intensity is low.

Therefore, there are no organic photovoltaic modules in the current state of the art that comprise organic photovoltaic cells suitable for indoor radiation where the incident light intensity is limited.

Thus, one of the purposes of the invention is to remedy at least in part the shortcomings of the photovoltaic modules, and their manufacturing method, of the prior art.

According to a first aspect, the invention relates to a photovoltaic module comprising:
a substrate made of glass or a polymer material,
at least two photovoltaic cells, a first photovoltaic cell and a second photovoltaic cell, on said substrate, each of said two photovoltaic cells comprising:
   i. a cathode layer of indium-tin oxide covering said substrate,
   ii. a first interfacial layer of zinc oxide or aluminum-doped zinc oxide, said first interfacial layer covering said cathode,
   iii. a photovoltaic active layer covering said first interfacial layer, and
   iv. a second interfacial layer comprising a polymer blend of poly(3,4-ethylenedioxythiophene) and sodium poly(styrene sulfonate), said second interfacial layer constituting the anode and covering said photovoltaic active layer, said second interfacial layer being continuous, having an organic fibrous structure and an average thickness of between 100 nm and 400 nm,
   the second interfacial layer of the first photovoltaic cell being in contact with the indium-tin oxide layer of the second photovoltaic cell.

According to this first aspect, the module according to the invention has a conversion efficiency of between 14% and 21%, which is sufficient to be able to use the photovoltaic module effectively under indoor radiation. In particular, with the photovoltaic module according to the invention, the photo-generated charge losses are minimized, and their transfers between the different layers of the organic photovoltaic cells are improved so as to have an overall stability of the photovoltaic module. Indeed, the general stability of an organic photovoltaic module depends on the intrinsic stability of the different layers constituting each of the organic photovoltaic cells of the organic photovoltaic module but also on the stability of the interfaces between each of these layers. Furthermore, with the photovoltaic module according to the invention, doing away with the silver layer as anode and having a single layer used as a second interfacial layer and anode results in organic photovoltaic cells comprising fewer interfaces than in those used in the current state of the art. Therefore, the risk of losing photo-generated charges is reduced and the risk of having interface oxidation is also reduced.

Also, it should be noted that a layer comprising a polymer blend of poly(3,4-ethylenedioxythiophene) and sodium poly(styrene sulfonate) is used here as an anode and not a layer comprising a high conductivity material conventionally used to play the role of anode, such as a silver layer for example, because by directly applying the layer comprising a high conductivity material on the photovoltaic active layer, there is a risk of penetration of particles (for example metallic silver nanoparticles) based on this high conductivity material through the active layer; this can lead to short circuits.

Chemical reactions, usually oxidation, are activated by temperature and can occur at the active layer/metal electrode interface. This problem does not exist when applying an electrode consisting of a layer comprising a polymer blend of poly(3,4-ethylenedioxythiophene) and sodium poly(styrene sulfonate) to the active layer.

Furthermore, it is already well known that for indoor radiation, the shunt resistance is critical for the performance of organic photovoltaic cells in particular and it is this resistance that limits the fill factor. The photovoltaic module according to the invention then has a higher shunt resistance than photovoltaic modules of the current state of the art and a lower series resistance than photovoltaic modules of the current state of the art so as to have a high and stable fill factor between 50 and 1000 lux, in particular between 65% and 73%.

Also, since the photovoltaic module according to the invention does not comprise a silver layer as an anode, this photovoltaic module has a low dead surface and a higher active surface than in photovoltaic modules of the prior art.

In the sense of the present invention, dead surface means the total surface of the photovoltaic module, which takes into account the set of layers deposited for the manufacture of each of the organic photovoltaic cells constituting the photovoltaic module, minus the active surface. The dead surface corresponds to the area of the interconnection between each of the organic photovoltaic cells, the interconnection area being outside the active surface.

In the sense of the present invention, active surface means the surface common to the various superimposed layers forming each of the organic photovoltaic cells making up the photovoltaic module. The active surface comprises the electrodes and is therefore delimited by the surface of the two upper and lower electrodes.

The fact that the silver layer is no longer used as an anode allows layers with a larger surface area to be applied. Thus, the power of the photovoltaic module according to the invention is improved and the generated photo-current is increased. In particular, the photovoltaic module according to the invention has a 20 to 30% larger active surface compared to the configuration of modules using a silver layer as an anode. The elimination of the silver layer as an anode and the presence of such a second interfacial layer allows the photovoltaic module according to the invention to have a fill factor of more than 70%.

Also, the fact that the silver layer is not used as anode has the advantage of having a module with less interface, and thus a better stability and a lower manufacturing cost compared to the modules of the background art that comprise this silver layer as an anode.

Furthermore, in the module according to the invention, the series resistance between the second interfacial layer and the indium-tin oxide layer is low, which ensures a good interconnection between the cells.

Preferably, the second interfacial layer is transparent and has a transparency coefficient of less than 0.6. Thus, the photon absorption coefficient of the module is increased, and the performance of the module is thereby improved.

Preferably, the substrate is transparent and the second interfacial layer comprising a polymer blend of poly(3,4-ethylenedioxythiophene) and sodium poly(styrene sulfonate) is also transparent. Thus, it is possible to produce photo-generated loads on both sides of the photovoltaic module to further improve the conversion efficiency of each of the organic photovoltaic cells included in the photovoltaic module.

In a particular mode of the invention, under conventional radiation conditions, namely when the module is exposed to an AM 1.5 solar spectrum, the number of charges generated by the photovoltaic module according to the invention is advantageously limited compared to the photovoltaic modules currently used. In the currently used photovoltaic modules with organic photovoltaic cells with an inverse structure, for a good extraction of photo-generated charges and for a good operation of the module, it is necessary to have a top metal electrode with high electrical conductivity as an anode. However, the photovoltaic cells of the module of the invention do not include this metal electrode. In the invention, in each photovoltaic cell, it is the second interfacial layer that acts as the anode and has sufficient electrical conductivity to ensure both the extraction of charges and their transfer to the other layers of the photovoltaic cells when the photovoltaic module is exposed to indoor radiation (generally less than or equal to 1000 lux). Therefore, to enable the photovoltaic module to operate optimally under indoor radiation, in this embodiment, the second interfacial layers have a square resistance between 100Ω/□ and 600Ω/□.

In a particular embodiment of the invention, the conversion efficiency is further improved. Therefore, in this embodiment, the second interfacial layers have a roughness Ra equal to or less than 5 nm.

In a particular embodiment of the invention, the photovoltaic active layers comprise a polymer blend comprising methyl [6,6]-phenyl-C₆₁-butanoate associated with poly(thieno[3,4-b]-thiophene.

In a particular mode of the invention, it is advantageous that the photovoltaic module can be applied to different objects and that the module can conform to them. Therefore, in this embodiment, the substrate is flexible.

According to a second aspect, the invention concerns the use of the photovoltaic module described above on products such as light sports equipment, strollers, packaging, particularly luxury packaging, luggage, leather goods, interior decor, electronics, point-of-sale advertising panels, personal protective equipment, gloves, toys and edutainment, furniture, sunshades, textiles, bicycles and automobiles. The invention also relates to the use of the above-described photovoltaic module under radiation less than or equal to 1000 lux.

According to a third aspect, the invention relates to a method for manufacturing a photovoltaic module as defined above, comprising the following steps:

a) providing a substrate made of glass or a polymer material,
b) forming two indium-tin oxide layers on said substrate, each of said indium-tin oxide layers constituting the cathode of each of said photovoltaic cells;
c) making two first interfacial layers, each of said two first interfacial layers being made on each of said indium-tin oxide layers;
d) making two photovoltaic active layers, each of said photovoltaic active layers being made on each of said first interfacial layers;
e) making two second interfacial layers, each of said second interfacial layers being made on each of said photovoltaic active layers and constituting the anode of each of said photovoltaic cells;
the method being characterized in that steps c) to e) are each performed by depositing ink compositions by digital inkjet printing, followed by a heat treatment,
said ink composition used in step e) comprising a polymer blend of poly(3,4-ethylenedioxythiophene) and sodium poly(styrene sulfonate).

According to this third aspect, it is not necessary to carry out, for the manufacture of the photovoltaic module according to the invention, a heat treatment higher than 130° C. currently used to anneal generally the silver layer, or similar layers used as anodes in organic photovoltaic cells with an inverse structure in particular. The advantage of not using heat treatment is that the other layers of the organic photovoltaic cells are not affected by the high temperature. For example, photovoltaic modules can be used that include substrates with glass transition temperatures below 130° C.

In a particular mode of the invention, to further decrease the series resistances between each of the layers of the organic photovoltaic cells. Therefore, in this embodiment, between steps d) and e), a cleaning of the photovoltaic active layers is performed using a solvent selected from ethanol, butanol, methanol, isopropanol and ethylene glycol.

In a particular embodiment of the invention, a fast, economical, stable and easily reproducible manufacturing method is preferred. Therefore, in this embodiment, steps c) to e) are performed as follows:

c) depositing by digital inkjet printing on each of the two indium-tin oxide layers a first ink composition comprising zinc oxide nanoparticles or aluminum-doped zinc oxide (AZO) nanoparticles, followed by heat treatment, to form the first two interfacial layers;
d) depositing by digital inkjet printing on the first two interfacial layers a second ink composition comprising a polymer blend comprising methyl [6,6]-phenyl-C₆₁-butanoate combined with poly(thienol[3,4-b]-thiophene) to form the two photovoltaic active layers; and
e) depositing by digital inkjet printing on the two photovoltaic active layers a third ink composition comprising a polymer blend of poly(3,4-ethylenedioxythiophene) and sodium poly(styrene sulfonate), followed by heat treatment, to form the two second interfacial layers.

Also, in this embodiment, preferably the heat treatments of steps c) to e) are annealing treatments carried out at a temperature between 70° C. and 130° C., for a time between 1 and 5 minutes.

Preferably, in this embodiment:
the heat treatment of step c) is carried out on a hot plate at a temperature of 85° C. for 3 minutes;
the heat treatment of step d) is carried out on a hot plate at a temperature of 85° C. for 2 minutes; and
the heat treatment of step e) is carried out on a hot plate at a temperature of 120° C. for 1 to 5 minutes.

Preferably, in this embodiment, step b) of making the two indium-tin oxide layers is performed by vacuum deposition.

Currently, chemical reactions in the presence of oxygen and water vapor can degrade the performance of photovoltaic modules and generate the so-called S-Shape which results in a significant degradation of the fill factor of the photovoltaic module. Therefore, using the method according to the invention and in a particular mode of the invention, steps c) to e) of digital inkjet printing deposition are performed under ambient air atmospheres.

Preferably, it is noted that step e) of depositing a third ink composition by digital inkjet printing may be performed by depositing an ink having a viscosity of less than 10 mPa·s at 20° C. and comprising:
between 90% and 98% by volume, relative to the total volume of the composition, of a solution of sodium Poly(3,4-ethylenedioxythiophene)-poly(styrene sulfonate), and
between 2% and 10% by volume relative to the total volume of an additive composition comprising:
between 2% and 5% by volume relative to the total volume of all additives in the additive composition of a surfactant,
between 0.8% and 2% by volume relative to the total volume of all additives in the ethylene glycol additive composition,
between 0.4% and 1% by volume relative to the total volume of all additives in the ethanolamine additive composition, and
between 0.8% and 2% by volume relative to the total volume of all additives in the additive composition of a glycerol.

Further advantages and features of the present invention will be apparent from the following description, made with reference to the attached figures and the following examples:

FIG. 1 represents a schematic cross-sectional view of a photovoltaic cell of a conventional structure;

FIG. 2 represents a schematic cross-sectional view of a photovoltaic module comprising photovoltaic cells according to a particular mode according to the invention;

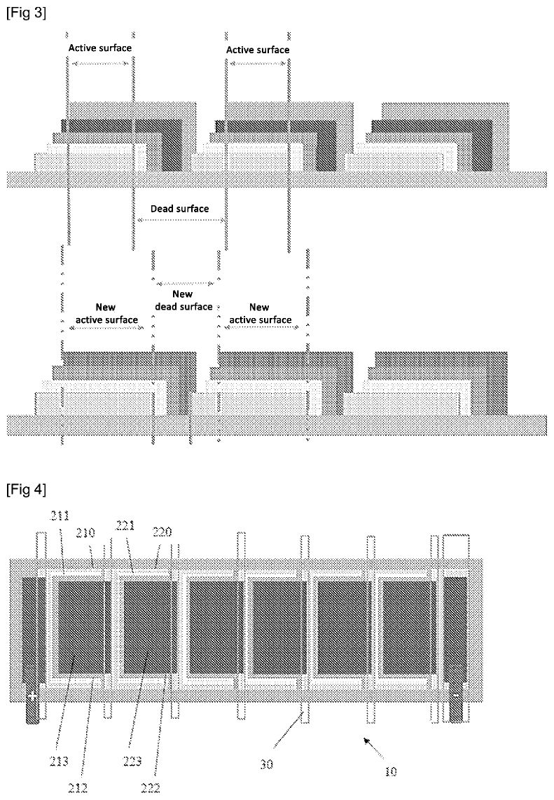

FIG. 3 represents a comparison between a module comprising photovoltaic cells of the current state of the art and a photovoltaic module comprising photovoltaic cells according to a particular mode according to the invention; and

FIG. 4 represents a schematic top view of a photovoltaic module comprising photovoltaic cells according to a particular mode according to the invention.

FIG. 1 is described in the foregoing disclosure of the prior art, while FIGS. 2 to 4 are described in more detail at the level of the examples that follow, which illustrate the invention without limiting its scope.

### EXAMPLES

Products
a glass substrate 20 coated with a discontinuous indium-tin oxide layer so that the substrate is partly covered with indium-tin oxide layers 210 and 220 which will form the cathodes of the various organic photovoltaic cells 21 and 22 described below
a flexible substrate 20 made of PET (Polyethylene terephthalate) or PEN (Polyethylene 2,6-naphthalate) also coated with a discontinuous indium-tin oxide layer so that the substrate is partly covered with indium-tin oxide layers 210 and 220 which will form the cathodes of the various organic photovoltaic cells 21 and 22 described below
cleaning solvents:
in the case of rigid glass substrates: deionized water, Acetone, Ethanol, Isopropanol, and
in the case of flexible substrates, since they are protected by plastic films, they do not need to be cleaned as in the case of rigid substrates;
first ink compositions (first interfacial layers 211 and 221 of the photovoltaic cells 21 and 22 of the photovoltaic module 10 of FIG. 2)
ink E11 of laboratory-synthesized zinc oxide nanoparticles, the formulation of which is detailed in Example 1.
ink E12 of aluminum-doped zinc oxide (AZO) nanoparticles marketed by the company GENES′INK, synthesized in the laboratory.
second ink compositions (photovoltaic active layers 212 and 222 of the photovoltaic cells 21 and 22 of the photovoltaic module 10 of FIG. 2):
polymer blend E21 of methyl [6,6]-phenyl-C₇₁-butanoate (marketed by Nano-C® under the trade name PC70BM) and poly(thienol[3,4-b]-thiophene (marketed by Raynergy Tek® under the trade name PV2000);
polymer blend E22 of methyl [6,6]-phenyl-C₇₁-butanoate (marketed by Nano-C® under the trade name PC70BM) and poly(thienol[3,4-b]-thiophene (marketed by 1-Materials under the trade name PTB7-Th);
O-xylene as a solvent (ortho-xylene of the formula C₆H₄(CH₃)₂); and
Tetralin (1,2,3,4-tetrahydronaphthalin) as an additive.

The PV2000 polymer of the blend E21 or the PTB7-Th polymer of the blend E22 are present in these second ink compositions at 10 mg/mL.

The weight ratio between the PV2000 polymer of the blend E21 or the PTB7-Th polymer of the blend E22 and the PC70BM is 1:1.5

The volume ratio between the solvent O-xylene and the additive Tetralin is 97:3 in these second compositions.

A second ink composition is made by adding the solvent and the additive to the polymer blend E21 or E22 and maintaining this blend for 24 hours under stirring on a hot plate at 80° C. at a speed of 700 RPM.
third ink compositions (second interfacial layers 213 and 223 of the photovoltaic cells 21 and 22 of the photovoltaic module 10 of FIG. 2):
PEDOT:PSS marketed by Agfa® under the trade name IJ 1005 or PEDOT:PSS marketed by Agfa® under the trade name ORGACON S315;
Triton X-100 (4-(1,1,3,3-tetramethylbutyl)phenyl-polyethylene glycol of the formula-Oct-C₆H₄—(OCH₂CH₂)ₓOH, x=9-10) marketed by Merck® as a detergent/surfactant;
Ethanediol (or ethylene glycol, formula HOCH2CH2OH) marketed by Merck®;
glycerol (1,2,3-Propanetriol or glycerin, formula HOCH₂CH(OH)CH2OH) marketed by Merck®;
Deionized water, produced in the laboratory or marketed by the company PURELAB® classic under the brand name ELGA® for water.

### Tests

Roughness measurement Ra

These measurements are performed with an atomic force microscope (Nanoscope III Multimode SPM from Brucker®, used in intermittent contact mode (or “tapping mode”), with hq:nsc15 tips marketed by MiKromasch® and having a radius of curvature of 8 nm), the measurements were performed on different samples of photovoltaic cells according to the invention and according to the background art.

Layer thickness measurement

The measurement of the thickness of the printed layers is carried out by means of a DektakXT stylus profilometer marketed by BRUKER, at a scratch made with a cutter blade (thereby creating a channel having the thickness of the deposit). This is a contact profilometer that measures variations in relief by vertically moving a pointed stylus that scans the surface applying a constant contact force and reveals any unevenness. The sample is placed on a plate that allows it to move with a given speed and over a chosen distance. The thickness values presented in this patent application are the average of five measurements taken at six different points on a single step of a sample. Before taking measurements, the length of the scanned area, its duration, the force of the stylus and the measurement range must be defined.

Electrical resistivity measurement

This measurement is performed using the 4-point technique, as follows:
we place the 4 points aligned far from the edges of the layer to be characterized;
these 4 points are equidistant from each other; and
current is generated by a current generator between the outer points, while the voltage is measured between the inner points. The ratio of the measured voltage to the current flowing through the sample gives the resistance of the section between the inner points.

Viscosity measurement:

The viscosity of a fluid is manifested by its resistance to deformation or relative sliding of its layers. During the flow of a viscous fluid in a capillary tube for example, the speed of the molecules (v) is highest in the axis of the tube and decreases until it approaches zero at the wall, while between the layers a relative sliding develops; hence the appearance of tangential forces of friction. The tangential forces, in fluids, depend on the nature of the fluid considered and the regime of its flow.

The viscometer used is of the Ubbelhode type; it is placed in a thermostat maintained at a constant temperature (25° C. in our case study). We measure the flow time of a constant volume V defined by two reference marks (M1 and M2) located on either side of a small tank atop the capillary.

Aging measurement:

Aging under permanent light soaking and thermal aging at 85° C.

Morphology characterization:

AFM (Atomic Force Microscope) measurements to reproduce the surface topography and TEM (Transmission Electron Microscopy) to validate the crystalline character of the materials as well as the sizes of the nanoparticles present in the layers.

Conversion efficiency

The conversion efficiency is the ratio of the generated power and the power of the incident radiation under indoor radiation. The internal measuring bench consists of an insulated enclosure in which the characterizations of the organic photovoltaic cells and modules are carried out. A spectrometer is used to measure the incident luminous flux (from different light sources such as LED, neon, halogen and compact fluorescent lamps) in W/m² and Lux. Measurements are also made with a Keithley 2450 source meter (20 mV-200 V, 10 nA-1 A).

### Example 1: Obtaining a First Example of a First Ink Composition E11 for First Interfacial Layer 211 and 221

### 1.1. Synthesis of ZnO by the Polyol Technique^{[4]}

Equipment used:

Two round-bottom flasks, Bromine column, Oil bath, Argon bottle, syringe filter, heating plate and magnetic stirrer, ultrasonic bath, Ardeje A100® printer, Ardeje OD100® printer, print head of the following brands: KONICA®, RICOH®.

Procedure:
First, a quantity of 2.207 g KOH is weighed into a 250 mL flask. Then 115 mL of methanol is added. In another larger flask, 4.101 g of zinc acetate is added with 210 mL of methanol under stirring and then 115 mL of water is added.
Then, this large flask is fixed in an oil (or water) bath under stirring and argon at 60° C. on a hot plate.
In addition, KOH is dissolved in an ultrasonic bath and then added dropwise to the flask.
A change of color from transparent to opaque is observed. After a few minutes, the solution becomes transparent again.
The blend is then stirred for another 3 hours, after which a white suspension of ZnO has formed.
   1.2 Manufacture of Ink E11 from Synthesized ZnO Nanoparticles
The zinc oxide ZnO obtained from the Polyol technique in Example 1.1 is cooled in a cold bath and the ZnO particles are separated by centrifugation (12 min and 7800 rpm) and dispersed in butanol using ethylene glycol as a surfactant.
An ink E11 of ZnO particles with a nanoparticle concentration of 4 mg/mL is obtained.
Before inkjet printing, the ink E11 is pre-filtered with a 0.45 micrometer cellulose acetate (CA) filter.

### Example 2: Obtaining a Second Example of a First Ink Composition E12 for First Interfacial Layer 211 and 221

We use the aluminum-doped zinc oxide (AZO) nanoparticle ink marketed by the GENES′INK® company in the following way: before inkjet printing, the ink is first placed in an ultrasound bath for 2 minutes at room temperature, then filtered with a 0.45 micrometer cellulose acetate filter. The ink E12 is obtained.

### Example 3: Obtaining a Third Example of a First Ink Composition E13 for First Interfacial Layer 211 and 221

### 3.1 Synthesis of AZO Nanoparticles

This synthesis is done by the following protocol, according to the one described in the scientific publication^{[3]}:
Zinc acetate, aluminum isopropylate and distilled water are introduced into a flask containing anhydrous ethanol.
After heating at 80° C. for 30 minutes, potassium hydroxide dispersed in ethanol is added dropwise to the flask while heating at 80° C. for 16 hours: AZO nanoparticles are thus synthesized.
These nanoparticles are then separated from the solution by centrifugation and dispersed in an alcohol-based solvent using ethanolamine (EA).
By this method, AZO NC nanoparticles (acronym for: “Aluminum-Doped Zinc Oxide nano-crystals”) at Al doping levels ranging from 0% (undoped baseline) up to 0.8 at % were produced by varying the initial ratio of aluminum isopropylate precursor to zinc acetate, and keeping all other parameters constant.
   3.2 Method of Manufacturing Ink E12 from Synthesized AZO Nanoparticles
The AZO obtained from the Polyol technique in Example 3.1 is cooled in a cold bath and the AZO particles are separated by centrifugation (12 min and 7800 rpm) and dispersed in butanol using ethylene glycol as a surfactant.
An ink E12 of AZO particles with a nanoparticle concentration of 2 mg/mL is obtained.
Before inkjet printing, the ink E12 is pre-filtered with a 0.45 micrometer cellulose acetate (CA) filter.

### Example 4: Obtaining Second Ink Compositions E21 and E22 for Photovoltaic Active Layer 212 and 222

Depending on whether PC70BM is used in combination with PV2000 or PC70BM in combination with PTB7-Th, the ink compositions E21 and E22 are obtained respectively, the compositions of which are detailed in Table 1 below:

TABLE 1

| Composition | | |
|---|---|---|
| | E21 | E22 |

| | | | | |
|---|---|---|---|---|
| PC70BM | 15 | mg | 15 | mg |
| PTB7-Th | 10 | mg | | |
| PV2000 | | | 10 | mg |
| O-xylene | 1 | mL | 1 | mL |
| Tetralin | 60 | microliters | 60 | microliters |

The ink composition E21 is obtained as follows:
10 mg PTB7-th blended with 15 mg PC70BM (corresponding to a 1:1.5 mass ratio) in 1 milliliter of o-xylene and 60 microliters of tetralin.
The blend is put under magnetic stirring on a hot plate at 80° C. for 24 hours.
Before printing, the ink is pre-filtered with a 0.45 micrometer AC filter.
The printed layers then undergo thermal annealing on a hot plate at 85° C. for 2 minutes.

The ink composition E22 is obtained as follows:
10 mg PV2000 mixed with 15 mg PC70BM (corresponding to a mass ratio of 1:1.5) in 1 milliliter of o-xylene and 60 microliters of tetralin.
The blend is put under magnetic stirring on a hot plate at 80° C. for 24 hours.
Before inkjet printing, the E22 ink is filtered with a 0.45 micrometer AC filter.
After inkjet printing of E12 or E22, photovoltaic active layers are obtained which, once printed, are subjected to thermal annealing on a hot plate at 85° C. for 2 minutes.

### Example 5: Obtaining Third Ink Compositions E31 and E32 for Second Interfacial Layers 213 and 223

These third ink compositions E31 and E32 for second interfacial layers 213 and 223 are obtained as follows:

PEDOT:PSS is filtered with a 0.45 μm filter;

500 μl Triton X-100 (a) is mixed with 200 μl Ethylene Glycol (b), 200 μl Glycerol (c) and 100 μl Ethanolamine (d) in 9 mL deionized water (e);
the blend thus obtained is put under magnetic stirring at 50° C. on a hot plate for 30 minutes, then under magnetic stirring at room temperature for 20 minutes;
the initially filtered PEDOT:PSS is mixed with the blend thus obtained after stirring, in the following proportions: 30 μl of the blend of 3 additives in deionized water for 1 mL of

PEDOT:PSS; the resulting blend (with PEDOT:PSS) is placed under magnetic stirring on a hot plate at room temperature for at least 1 hour; and
the final solution thus obtained E31 is degassed for 3 to 5 minutes in an ultrasonic bath before printing.

Depending on whether PEDOT:PSS IJ1005 or PEDOT:PSS ORGACON S315 is used, the ink compositions E31 and E32 are obtained, respectively, whose compositions are detailed in the two tables 2 and 3 below:

TABLE 2

| | | Solution X | |
|---|---|---|---|
| Composition | | (a + b + c + d) | |
| a-Triton x-100 | a | 500 | μL |
| b-Ethylene Glycol | b | 200 | μL |
| c-Glycerol | c | 200 | μL |
| d-Ethanolamine | d | 100 | μL |
| e-Deionized water | e | 9 | mL |

TABLE 3

| Composition | | |
|---|---|---|
| | E31 | E32 |

| | | | | |
|---|---|---|---|---|
| IJ1005 | 1 | mL | | |
| Orgacon S315 | | | 1 | mL |
| Solution X | 30 | μL | 30 | μL |
| a) + b) + c) + d) | | | | |

### Example 6: Obtaining Examples of Photovoltaic Modules According to the Invention

OPV cells according to the invention are produced according to the following method:

For rigid substrates:
Cleaning the rigid glass substrate with structured ITO layer by successive soaking in 4 different cleaning baths:
Bath 1: Deionized water at 20-40° C. for 10-15 minutes,
Bath 2: Acetone at 20-40° C. for 10-15 minutes,
Bath 3: Ethanol at 20-40° C. for 10-15 minutes,
Bath 4: Isopropanol at 20-40° C. for 10-15 minutes;
Printing ink E11, E12, or E13 on each of the indium tin oxide layers 210 and 220 followed by annealing at 85° C. for 5 minutes to obtain the first interfacial layers 211 and 221;
Printing ink E21 or E22 on each of the first interfacial layers 211 and 221 followed by annealing at 85° C. for 2 minutes to obtain the active layer 212 and 222;
Cleaning the active layer 212 and 222 with an alcohol (Ethanol, Butanol, Isopropanol);
Printing the ink E31 or E32 on each of the active layers 212 and 222, followed by annealing at 120° C. for 2 minutes so as to have a second interfacial layer 213 and 223 with a thickness of between 100 and 400 nm, in particular about 350 nm, the second interfacial layer 213 of the first photovoltaic cell 21 being in contact with the indium-tin oxide layer 220 of the second photovoltaic cell 22;
Cleaning the second interfacial layer 213 and 223 with an alcohol (Ethanol, Butanol, Isopropanol) to improve the conductivity of the second interfacial layer 213 and 223.

For flexible substrates:
The ITO/PET substrate is protected by two plastic films on both sides:
this substrate is glued with double-sided tape to a glass slide of the same size;
The plastic film covering the ITO side of the substrate is then removed;
Printing ink E11 (or E12) on each of the indium tin oxide layers 210 and 220 followed by annealing at 85° C. for 5 minutes to obtain the first interfacial layers 211 and 221;
Printing ink E21 or E22 on each of the first interfacial layers 211 and 221 followed by annealing at 85° C. for 2 minutes to obtain the active layer 212 and 222;
Cleaning the active layer 212 and 222 with an alcohol (Ethanol, Butanol, Isopropanol);
Printing the ink E31 or E32 on each of the active layers 212 and 222, followed by annealing at 120° C. for 2 minutes so as to have a second interfacial layer 213 and 223 with a thickness of between 100 and 400 nm, in particular about 350 nm, the second interfacial layer 213 of the first photovoltaic cell 21 being in contact (the contact is designated by the reference 30 in FIG. 4) with the indium-tin oxide layer 220 of the second photovoltaic cell 22;
Cleaning the E31 or E32 layer with an alcohol (Ethanol, Butanol, Isopropanol);
Detaching the resulting photovoltaic module from the plastic film.

At the end of the manufacturing method, a photovoltaic module 10 is obtained comprising the following organic photovoltaic cells 21 and 22, which are summarized in Table 4 below and which then comprise a second interfacial layer 213 and 223 as an anode which has a micrometric organic fiber structure.

TABLE 4

| | | | | | Cleaning |
|---|---|---|---|---|---|
| OPV cells | Composition of the | Composition of the | Active | Composition of the | of the |
| according to | first interfacial | active photovoltaic | layer | second interfacial | interfacial |
| the invention | layer 211 and 221 | layer 212 and 222 | cleaning | layer 213 and 223 | layer |
| C1 | E11 | E21 | Yes | E31 | yes |
| C2 | E12 | E21 | Yes | E31 | yes |
| C3 | E11 | E22 | Yes | E31 | yes |
| C4 | E12 | E22 | Yes | E31 | yes |
| C5 | E11 | E21 | Yes | E32 | yes |
| C6 | E12 | E21 | Yes | E32 | yes |
| C7 | E11 | E22 | Yes | E32 | yes |
| C8 | E12 | E22 | Yes | E32 | yes |

### Example 7: Obtaining Examples of Background Art/Control Modules

Photovoltaic modules comprising OPV cells in accordance with the background art are produced according to the following method:

1) ITO substrates (purchased from Lumtec®, 15 Ohm sq-1) were carefully cleaned by sonication in deionized water, acetone, ethanol and then in IPA (isopropanol) (10 minutes per bath);
2) A solution of ZnO (or AZO) nanoparticles in IPA and 0.2% (v/v) ethanolamine was deposited by centrifugation (a.k.a. spin coating) at 1500 rpm for 1 min and dried at 80° C. for 5 min on a hot plate;
3) PTB7-Th (or PV2000) and PC70BM are mixed with a mass ratio of 1:1.5 in o-xylene as solvent and tetralin as additive with a polymer concentration of 10 mg/mL (the ratio between solvent and additive is 97:3 v/v). A layer with a nominal thickness of 90-100 nm was deposited by spin coating at 2700 rpm for 2 minutes;
4) A thin layer of poly (3,4-PEDOT:PSS) (S315) was deposited by spin coating on the organic layer at the speed of 3000 rpm for 60 s, then heated on a hot plate at 120° C. for 5 minutes;
5) For the anode, samples were placed in an MBRAUN evaporator inside a glove box, in which Al metal electrodes (100 nm) were thermally evaporated under a pressure of 2×10-7 Torr through a mask.
6) making a photovoltaic module comprising such organic photovoltaic cells and wherein the anode of one photovoltaic cell adjacent to another is in contact with the indium-tin oxide layer of the latter to ensure ohmic contact between each of the organic photovoltaic cells of the photovoltaic module.

It should also be noted that FIG. 3 shows the gain in active surface area and the loss in dead surface area of the module according to a particular embodiment according to the invention (module located in the lower part of FIG. 3) compared to a module of the current state of the art (module located in the upper part of FIG. 3) which comprises as an anode a metallic layer for example applied on a second interfacial layer 213 and 223 itself applied on an active layer 212 and 222.

### Example 8: Characterization of the OPV Cells Obtained in Examples 6 and 7

The various photovoltaic modules comprising the OPV cells, according to the invention, have been characterized according to the tests indicated above and the results of these characterizations in Table 5 below.

TABLE 5

| | Light | | Filling | |
|---|---|---|---|---|
| OPV cells according | intensity | Irradiance | factor | Yield |
| to the invention | in lux | in mW/cm² | in % | as a % |
| C1 | 1000 | 0.3 | 68 | 16.5 |
| C2 | 1000 | 0.3 | 72 | 18.2 |
| C3 | 1000 | 0.3 | 69 | 16.9 |
| C4 | 1000 | 0.3 | 73 | 20.1 |
| C5 | 1000 | 0.3 | 64 | 14.5 |
| C6 | 1000 | 0.3 | 70 | 15.6 |
| C7 | 1000 | 0.3 | 65 | 14.7 |
| C8 | 1000 | 0.3 | 71 | 16.1 |

The OPV cells according to the invention C1 to C8 show that the problem of printing both the ETL (electron transport layer) and the anode layer made of PEDOT-PSS material, of a photovoltaic cell is solved. In particular, such cells are advantageous when subjected to low radiation, especially indoor radiation. It is thus possible to produce a photovoltaic module 10 comprising several organic photovoltaic cells 21 and 22 each composed of 3 layers printed on a first transparent conductive electrode present on the flexible plastic or rigid glass substrate, or composed of 4 layers printed on a flexible plastic or rigid glass substrate free of any material.

The invention consists of formulating a PEDOT-PSS solution that is compatible with the inkjet printing method and that has electrical conductivity characteristics that are sufficient, in particular, to dispense with the application of an anode to the second interfacial layer so that the second interfacial layer is itself the anode. This formulation allows us to use a high conductivity PEDOT-PSS, which is traditionally used in the HTL (hole transport layer), to obtain a layer that is both an ETL and an anode layer.

The inkjet printing method combined with this formulation allows us to control the thickness of the printed layer, to optimize the electrical and optical characteristics of the material, as well as the structure of the second interfacial layer with the realization of an organic fibrous amorphous crystalline structure, having in particular organic fibers essentially oriented substantially vertically to promote the transport of the charges. The conversion efficiencies of the modules made using the present invention remain unique to date.

### Comparison:

Thus, a photovoltaic module designated “Margent” (M-silver) was manufactured. This Margent module comprises several cells C1 above indicated on which have been further applied a silver-based anode having a thickness of the order of 120 nm and an electrical resistivity of the order of 2.5 μΩ·cm as shown in the bottom figure of FIG. 3. The cell comprising silver is designated “Cargent” and has been characterized according to the tests listed previously and the results of these characterizations in Table 6 below.

TABLE 6

| | | Open | Short | | | | |
|---|---|---|---|---|---|---|---|
| | Light | circuit | circuit | Maximum voltage | Maximum current | Maximum power | Filling |
| | intensity | voltage | current | generated by the | generated by the | generated by the | factor |
| | in lux | (in V) | (in μA) | module (in V) | module (in μA) | module (in μW) | (in %) |
| Cargent | 200 | 2.41 | 23 | 1.78 | 11.21 | 19.9 | 36 |
| | 500 | 2.68 | 73 | 2.36 | 32.33 | 76.29 | 39 |
| | 1000 | 3.11 | 157 | 2.45 | 87.6 | 214.62 | 44 |
| | 5000 | 4.21 | 1780 | 3.02 | 1191 | 3596.82 | 48 |
| | 10000 | 4.42 | 4100 | 3.13 | 3068.5 | 9604.4 | 53 |
| | 100,000 | 4.69 | 31400 | 4.175 | 20450 | 85378.75 | 58 |
| | (equivalent | | | | | | |
| | to AM 1.5) | | | | | | |

By way of comparison, a photovoltaic module M1 according to the invention and comprising several photovoltaic cells C1 mentioned above has been manufactured. Cell C1 (without silver) was characterized according to the tests indicated previously and the results of these characterizations in Table 7 below.

TABLE 7

| | | Open | Short | Maximum | | | |
|---|---|---|---|---|---|---|---|
| | Light | circuit | circuit | voltage | Maximum current | Maximum power | Filling |
| | intensity | voltage | current | generated by the | generated by the | generated by the | factor |
| | in lux | (in V) | (in μA) | module (in V) | module (in μA) | module (in μW) | (in %) |
| C1 | 200 | 3.475 | 57 | 2.75 | 48.2 | 132.5 | 67 |
| | 500 | 3.675 | 140 | 3.00 | 116.6 | 349.8 | 68 |
| | 1000 | 3.825 | 258 | 3.00 | 223.6 | 661.2 | 68 |
| | 5000 | 4.125 | 1374 | 2.90 | 1074 | 3114.6 | 55 |
| | 10000 | 4.275 | 2849 | 2.850 | 2008 | 5722.8 | 47 |
| | 100,000 | 4.575 | 6950 | 2.73 | 4278 | 11764.5 | 37 |
| | (equivalent | | | | | | |
| | to AM 1.5) | | | | | | |

With the help of these two tables (Tables 6 and 7), we can clearly see that the behavior of each Margent and MC1 module will be very different with these Cargent and C1 cells, which have different photovoltaic performances as shown below.

Indeed, for the structure using PEDOT:PSS as electrode (C1), the filling factors are considerably better in the case of low radiation (less than 1000 Lux) which translates into an ease of charge extraction and a low charge recombination rate. In this case, the open circuit voltage values as well as the short circuit currents are considerably better than those obtained with Cargent cells using the silver layer under the same lighting conditions (radiation lower than 1000 Lux).

Moreover, the photovoltaic performance of module M1 (silver-free structure) including C1 cells continuously degrades with increasing light level (light radiation) and becomes very low under the solar spectrum AM 1.5 (100 mW/cm2) which proves the limits of use of this structure (efficiency only under indoor conditions).

It should also be noted that the photovoltaic performances obtained in the case of the Margent structure comprising the Cargent cells tend in an opposite direction (according to the luminous radiation to which the cells are exposed) compared to those obtained with M1 comprising the C1 cells. Indeed, beyond 1000 lux, the photovoltaic performances obtained with the Margent structure improve to reach a maximum of 100 mW/cm².

This is because the number of photo-generated charges under indoor conditions (radiation less than or equal to 1000 lux) is very small and therefore does not require a high conductivity electrode to ensure their collection. In this case, the PEDOT:PSS layer is able to perform the electrode function in the C1 cells of the M1 structure. In the case of a heavier lighting (radiation higher than 1000 lux) the PEDOT:PSS layer cannot transport and collect all the photo-generated charges, which causes an accumulation of charges at that layer and subsequently a degradation of the filling factors.

The silver layer of the Cargent cells is capable of collecting a large number of charges due to its high conductivity compared to PEDOT:PSS. The charge loss at the PEDOT:PSS/silver layer interface in the Cargent cells has less impact on the photovoltaic performances in the case of important lighting (radiation higher than 1000 lux according to which the number of photo-generated charges is very important) but it becomes more penalizing in the case of an interior lighting (radiation less than or equal to 1000 lux whereby the number of photo-generated charges is very weak) what explains the degradation of the performances of the Margent module exposed to radiation lower or equal to 1000 lux.

### LIST OF REFERENCES

[1] Sharaf Sumaiya, Kamran Kardel, and Adel EI-Shahat. “Organic Solar Cell by Inkjet Printing—An Overview.” 53, Georgia, USA: Technologies, 2017, Vol. 5.
[2] Peng, X., Yuan, J., Shen, S., Gao, M., Chesman, A. S. R., & Yin, H. (2017). “Perovskite and Organic Solar Cells Fabricated by Inkjet Printing: Progress and Prospects”, Adv. Funct. Mater. 2017, 1703704
[3] DRACULA TECHNOLOGIES' European patent application EP2960957, filed on Jun. 25, 2015 and published on Dec. 30, 2015.
[4] Maisch, P., Tam, K. C., Lucera, L., Egelhaaf, H. J., Scheiber, H., Maier, E., & Brabec, C. J. (2016). “Inkjet printed silver nanowire percolation networks as electrodes for highly efficient semitransparent organic solar cells”. Organic Electronics: Physics, Materials, Applications, 38, 139-143. https://doi.org/10.1016/j.orgel.2016.08.006.

1. A photovoltaic module comprising:
a substrate made of glass or a polymer material,
at least two photovoltaic cells, a first photovoltaic cell and a second photovoltaic cell, on said substrate, each of said two photovoltaic cells comprising:
i. a cathode layer of indium-tin oxide covering said substrate,
ii. a first interfacial layer of zinc oxide or aluminum-doped zinc oxide, said first interfacial layer covering said cathode,
iii. a photovoltaic active layer covering said first interfacial layer, and
iv. a second interfacial layer comprising a polymer blend of poly(3,4-ethylenedioxythiophene) and sodium poly(styrene sulfonate), said second interfacial layer constituting the anode and covering said photovoltaic active layer, said second interfacial layer being continuous, having an organic fibrous structure and an average thickness of between 100 nm and 400 nm,
the second interfacial layer of the first photovoltaic cell being in contact with the indium-tin oxide layer of the second photovoltaic cell.

2. The photovoltaic module according to claim 1, wherein said second interfacial layers have a square resistance between 100Ω/□ and 600Ω/□.

3. The photovoltaic module according to claim 1, wherein said second interfacial layers have a roughness Ra equal to or less than 5 nm.

4. The photovoltaic module according to claim 1, wherein said photovoltaic active layers comprise a polymer blend comprising methyl [6,6]-phenyl-C₆₁-butanoate associated with poly(thieno[3,4-b]-thiophene.

5. The photovoltaic module according to claim 1, wherein said substrate is flexible.

6. The use of said photovoltaic module as defined according to claim 1 on products such as light sports equipment, strollers, packaging, particularly luxury packaging, luggage, leather goods, interior decor, electronics, point-of-sale advertising panels, personal protective equipment, gloves, toys and edutainment, furniture, sunshades, textiles, bicycles and automobiles.

7. The use of said photovoltaic module as defined according to claim 1 under radiation equal to or less than 1000 lux.

8. A method of manufacturing a photovoltaic module as defined in claim 1, comprising the following steps:
a) providing a substrate made of glass or a polymer material;
b) forming two indium-tin oxide layers on said substrate, both of said indium-tin oxide layers constituting the cathode of each of said photovoltaic cells;
c) forming two first interfacial layers, both of said two first interfacial layers being formed on each of said indium-tin oxide layers;
d) forming two active photovoltaic layers, both of said photovoltaic active layers being formed on each of said first interfacial layers;
e) forming two second interfacial layers, both of said second interfacial layers being formed on each of said photovoltaic active layers and constituting the anode of each of said photovoltaic cells;
said method being characterized in that steps c) through e) are each performed by depositing ink compositions by digital inkjet printing followed by heat treatment, said ink composition used in step e) comprising a polymer blend of poly(3,4-ethylenedioxythiophene) and sodium poly(styrene sulfonate).

9. The method according to claim 8, wherein a cleaning of said photovoltaic active layers is performed between steps d) and e) using a solvent selected from ethanol, butanol, methanol, isopropanol and ethylene glycol.

10. The method according to claim 8, wherein steps c) to e) are performed as follows:
c) depositing by digital inkjet printing on each of the two indium-tin oxide layers a first ink composition comprising zinc oxide nanoparticles or aluminum-doped zinc oxide (AZO) nanoparticles, followed by heat treatment, to form the first two interfacial layers;
d) depositing by digital inkjet printing on said first two interfacial layers a second ink composition comprising a polymer blend comprising methyl [6,6]-phenyl-C₆₁-butanoate combined with poly(thienol[3,4-b]-thiophene) to form said two photovoltaic active layers; and
e) depositing by digital inkjet printing on said two photovoltaic active layers a third ink composition comprising a polymer blend of poly(3,4-ethylenedioxythiophene) and sodium poly(styrene sulfonate), followed by heat treatment, to form said two second interfacial layers.

11. The method according to claim 10, wherein the heat treatments of steps c) to e) are annealing treatments carried out at a temperature between 70° C. and 130° C., for a time between 1 and 5 minutes.

12. The method according to claim 11, wherein
the heat treatment of step c) is carried out on a hot plate at a temperature of 85° C. for 3 minutes;
the heat treatment of step d) is carried out on a hot plate at a temperature of 85° C. for 2 minutes; and
the heat treatment of step e) is carried out on a hot plate at a temperature of 120° C. for 1 to 5 minutes.

13. The method according to claim 8, wherein step b) of making said two indium-tin oxide layers is performed by vacuum deposition.

14. The method according to claim 10, wherein steps c) to e) of digital inkjet printing deposition are performed under ambient air atmospheres.

15. The method according to claim 10, wherein step e) of depositing by digital inkjet printing a third ink composition is performed by depositing an ink having a viscosity of less than 10 mPa·s at 20° C. and comprising:
between 90% and 98% by volume, relative to the total volume of said composition, of a solution of sodium poly(3,4-ethylenedioxythiophene)-poly(styrene sulfonate), and
between 2% and 10% by volume relative to the total volume of an additive composition comprising:
between 2% and 5% by volume relative to the total volume of all additives in the additive composition of a surfactant,
between 0.8% and 2% by volume relative to the total volume of all additives in the ethylene glycol additive composition,
between 0.4% and 1% by volume relative to the total volume of all additives in the ethanolamine additive composition, and
between 0.8% and 2% by volume relative to the total volume of all additives in the additive composition of a glycerol.
